(19) United States
(12) Patent Application Publication
(10) Pub. No.: US 2025/0151423 A1
(43) Pub. Date: May 8, 2025

(54) DETECTION DEVICE

(71) Applicant: Japan Display Inc., Tokyo (JP)

(72) Inventors: Akihiko FUJISAWA, Tokyo (JP); Kaoru ITO, Tokyo (JP); Shiori SEINO, Tokyo (JP)

(21) Appl. No.: 19/014,644

(22) Filed: Jan. 9, 2025

Related U.S. Application Data
(63) Continuation of application No. PCT/JP2023/024745, filed on Jul. 4, 2023.

(30) Foreign Application Priority Data
Jul. 11, 2022 (JP) 2022-111353

(51) Int. Cl. H10F 39/12; H04N 25/75; H04N 25/772; H10F 39/00

(52) U.S. Cl. CPC H10F 39/12; H10F 39/8037; H10F 39/8053; H10F 39/806; H04N 25/75; H04N 25/772

(57) ABSTRACT

According to an aspect, a detection device includes: a photodiode provided on a substrate; a light source disposed so as to face the photodiode; and a liquid crystal panel disposed between the photodiode and the light source in a direction orthogonal to the substrate. The liquid crystal panel includes a plurality of pixels. In plan view, the photodiode has a size larger than a size of each of the pixels, and the photodiode is disposed in a position overlapping the pixels. The liquid crystal panel is configured to bring at least one of the pixels overlapping the photodiode into a transmitting state and bring another of the pixels into a non-transmitting state.

### CROSS-REFERENCE TO RELATED APPLICATION

This application claims the benefit of priority from Japanese Patent Application No. 2022-111353 filed on Jul. 11, 2022 and International Patent Application No. PCT/JP2023/024745 filed on Jul. 4, 2023, the entire contents of which are incorporated herein by reference.

### BACKGROUND

### 1. Technical Field

What is disclosed herein relates to a detection device.

### 2. Description of the Related Art

International Publication WO 2012/060303 describes a display device with optical sensors that includes an active matrix substrate having a plurality of pixels and includes a plurality of optical sensors provided in a pixel area. In the display device with optical sensors of WO 2012/060303, the pixels and the optical sensors are provided on the same substrate.

In the display device with optical sensors of WO 2012/060303, the arrangement pitch of the optical sensors is larger than that of the pixels, so that the resolution of the optical sensors is lower than that of the pixels. Detection devices provided with such optical sensors are required to increase the resolution of detection.

For the foregoing reasons, there is a need for a detection device that includes an optical sensor and can improve the resolution of detection.

### SUMMARY

According to an aspect, a detection device includes: a photodiode provided on a substrate; a light source disposed so as to face the photodiode; and a liquid crystal panel disposed between the photodiode and the light source in a direction orthogonal to the substrate. The liquid crystal panel includes a plurality of pixels. In plan view, the photodiode has a size larger than a size of each of the pixels, and the photodiode is disposed in a position overlapping the pixels. The liquid crystal panel is configured to bring at least one of the pixels overlapping the photodiode into a transmitting state and bring another of the pixels into a non-transmitting state.

### BRIEF DESCRIPTION OF THE DRAWINGS

FIG. 1 is a sectional view schematically illustrating a detection device according to a first embodiment;

FIG. 2 is a block diagram illustrating a configuration example of the detection device according to the first embodiment;

FIG. 3 is a block diagram illustrating a configuration example of a detection control circuit according to the first embodiment;

FIG. 4 is a circuit diagram illustrating a sensor pixel;

FIG. 5 is a plan view schematically illustrating the sensor pixel according to the first embodiment;

FIG. 6 is a sectional view taken along VI-VI′ in FIG. 5;

FIG. 7 is a circuit diagram illustrating a pixel of a liquid crystal panel according to the first embodiment;

FIG. 8 is a sectional view schematically illustrating a configuration example of the liquid crystal panel according to the first embodiment;

FIG. 9 is a plan view schematically illustrating an arrangement relation between a plurality of the pixels of the liquid crystal panel and a plurality of the sensor pixels of an optical sensor in the detection device according to the first embodiment;

FIG. 10 is an explanatory diagram for explaining an exemplary detection operation of the detection device according to the first embodiment;

FIG. 11 is an explanatory diagram for explaining a method for generating a combined image by the detection device according to the first embodiment;

FIG. 12 is a diagram illustrating simulation results of detected images in detection devices according to an example and a comparative example;

FIG. 13 is a plan view schematically illustrating an arrangement relation between the pixels of a liquid crystal panel and the sensor pixels of the optical sensor in a detection device according to a second embodiment;

FIG. 14 is a sectional view schematically illustrating a configuration example of the liquid crystal panel according to the second embodiment;

FIG. 15 is an explanatory diagram for explaining an exemplary detection operation of the detection device according to the second embodiment;

FIG. 16 is an explanatory diagram for explaining an exemplary detection operation of a detection device according to a modification of the second embodiment;

FIG. 17 is a plan view schematically illustrating an arrangement relation between the pixels of the liquid crystal panel and the sensor pixels of the optical sensor in a detection device according to a third embodiment;

FIG. 18 is a plan view illustrating an exemplary sensitivity map of the optical sensor according to the third embodiment; and

FIG. 19 is a flowchart for explaining a method for calculating adjustment values by the detection device according to the third embodiment.

### DETAILED DESCRIPTION

The following describes modes (embodiments) for carrying out the present disclosure in detail with reference to the drawings. The present disclosure is not limited to the description of the embodiments given below. Components described below include those easily conceivable by those skilled in the art or those substantially identical thereto. In addition, the components described below can be combined as appropriate. What is disclosed herein is merely an example, and the present disclosure naturally encompasses appropriate modifications easily conceivable by those skilled in the art while maintaining the gist of the present disclosure. To further clarify the description, the drawings may schematically illustrate, for example, widths, thicknesses, and shapes of various parts as compared with actual aspects thereof. However, they are merely examples, and interpretation of the present disclosure is not limited thereto. The same component as that described with reference to an already mentioned drawing is denoted by the same reference numeral through the present disclosure and the drawings, and detailed description thereof may not be repeated where appropriate.

In the present specification and claims, in expressing an aspect of disposing another structure on or above a certain structure, a case of simply expressing “on” includes both a case of disposing the other structure immediately on the certain structure so as to contact the certain structure and a case of disposing the other structure above the certain structure with still another structure interposed therebetween, unless otherwise specified.

### First Embodiment

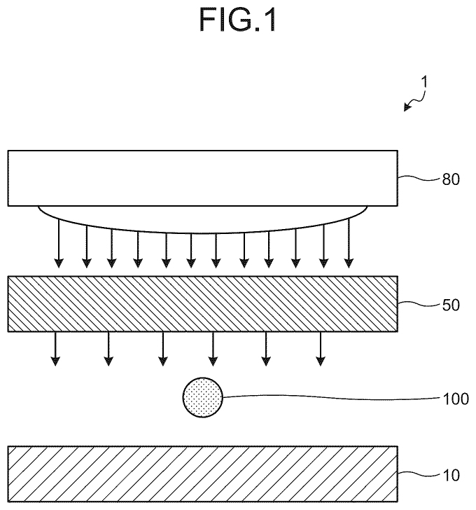

FIG. 1 is a sectional view schematically illustrating a detection device according to a first embodiment. As illustrated in FIG. 1, a detection device 1 includes an optical sensor 10, a liquid crystal panel 50, and a light source 80. The liquid crystal panel 50 and the light source 80 are stacked in this order above the optical sensor 10. An object to be detected 100 serving as a detection target is located between the optical sensor 10 and the liquid crystal panel 50.

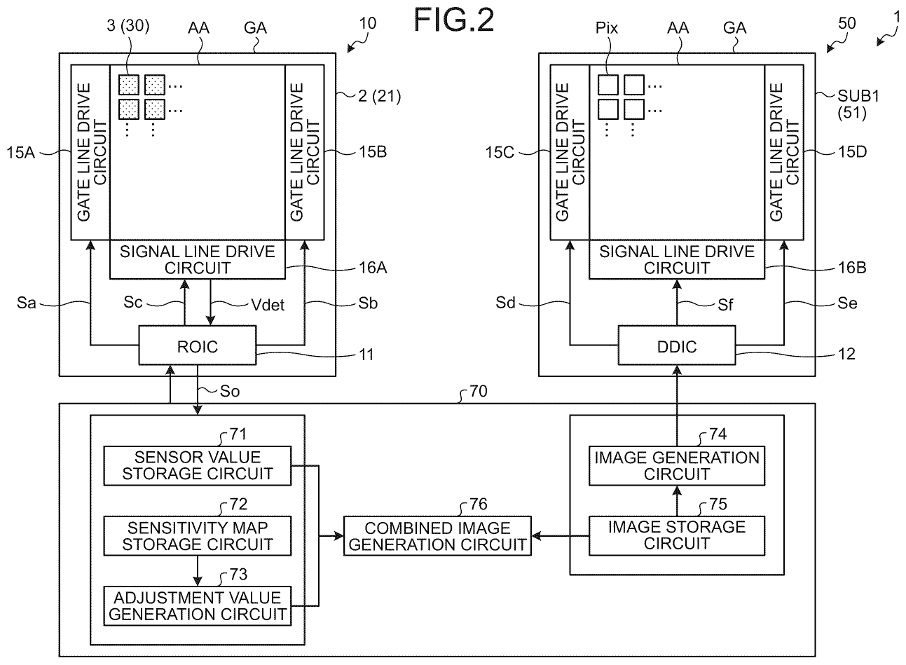

The light source 80 is disposed so as to face a plurality of photodiodes 30 of the optical sensor 10 (refer to FIG. 2) and emits parallel light toward the liquid crystal panel 50. The light source 80 may have any configuration. The light source 80 includes, for example, a light-emitting diode (LED) and a lens that emits light incident from the LED as the parallel light. The light source 80 may include a light-transmitting light guide plate and/or the like, as required. The light source 80 is disposed with a space (air layer) interposed between itself and the liquid crystal panel 50. However, the light source 80 may be bonded to the liquid crystal panel 50 with an optical resin or the like.

The liquid crystal panel 50 serves as an optical filter layer that switches between a transmitting state of light and a non-transmitting state of light for each of a plurality of pixels Pix (refer to FIG. 2). The liquid crystal panel 50 is disposed so as to face the photodiodes 30 of the optical sensor 10 (refer to FIG. 2) and located between the optical sensor 10 (photodiodes 30) and the light source 80. The liquid crystal panel 50 transmits part of the parallel light from the light source 80 toward the optical sensor 10. The photodiodes 30 of the optical sensor 10 (refer to FIG. 2) can detect information on the object to be detected 100 based on the parallel light transmitted through the liquid crystal panel 50.

The object to be detected 100 is, for example, microscopic objects such as cells. The detection device 1 can be applied to detection of the microscopic objects such as the cells. The object to be detected 100 is, however, not limited thereto, and may be a living body such as a finger, a thumb, a palm, or a wrist. For example, the optical sensor 10 may be configured as a fingerprint detection device to detect a fingerprint or a vein detection device to detect a vascular pattern of, for example, veins.

FIG. 2 is a block diagram illustrating a configuration example of the detection device according to the first embodiment. As illustrated in FIG. 2, the detection device 1 further includes a host integrated circuit (IC) 70 that controls the optical sensor 10 and the liquid crystal panel 50. The optical sensor 10 includes an array substrate 2, a plurality of sensor pixels 3 (photodiodes 30) formed on the array substrate 2, gate line drive circuits 15A and 15B, a signal line drive circuit 16A, and a detection control circuit (ROIC) 11.

The array substrate 2 is formed using a substrate 21 as a base. Each of the sensor pixels 3 is configured with a corresponding one of the photodiodes 30, a plurality of transistors, and various types of wiring. The array substrate 2 with the photodiodes 30 formed thereon is a drive circuit board for driving the sensor for each predetermined detection area and is also called a backplane or an active matrix substrate.

The substrate 21 has a detection area AA and a peripheral area GA. The detection area AA is an area provided with the sensor pixels 3 (photodiodes 30). The peripheral area GA is an area between the outer perimeter of the detection area AA and the outer edges of the substrate 21 and is an area not provided with the sensor pixels 3. The gate line drive circuits 15A and 15B, the signal line drive circuit 16A, and the detection control circuit 11 are provided in the peripheral area GA.

Each of the sensor pixels 3 is an optical sensor including the photodiode 30 as a sensor element. Each of the photodiodes 30 outputs an electric signal corresponding to light emitted thereto. More specifically, the photodiode 30 is a positive-intrinsic-negative (PIN) photodiode or an organic photodiode (OPD) using an organic semiconductor. The sensor pixels 3 (photodiodes 30) are arranged in a matrix having a row-column configuration in the detection area AA.

The detection control circuit 11 is a circuit that supplies control signals Sa, Sb, and Sc to the gate line drive circuits 15A and 15B, and the signal line drive circuit 16A, respectively, to control operations of these circuits. Specifically, the gate line drive circuits 15A and 15B output gate drive signals to sensor gate lines GLS (refer to FIG. 4) based on the control signals Sa and Sb. The signal line drive circuit 16A electrically couples a sensor signal line SLS selected based on the control signal Sc to the detection control circuit 11. The detection control circuit 11 includes a signal processing circuit that performs signal processing of a detection signal Vdet from each of the photodiodes 30.

The photodiodes 30 included in the sensor pixels 3 perform detection in response to the gate drive signals supplied from the gate line drive circuits 15A and 15B. Each of the photodiodes 30 outputs the electric signal corresponding to the light emitted thereto as the detection signal Vdet to the signal line drive circuit 16A. The detection control circuit 11 processes the detection signal Vdet from each of the photodiodes 30 and outputs a sensor value So based on the detection signal Vdet to the host IC 70. Thus, the detection device 1 detects the information on the object to be detected 100.

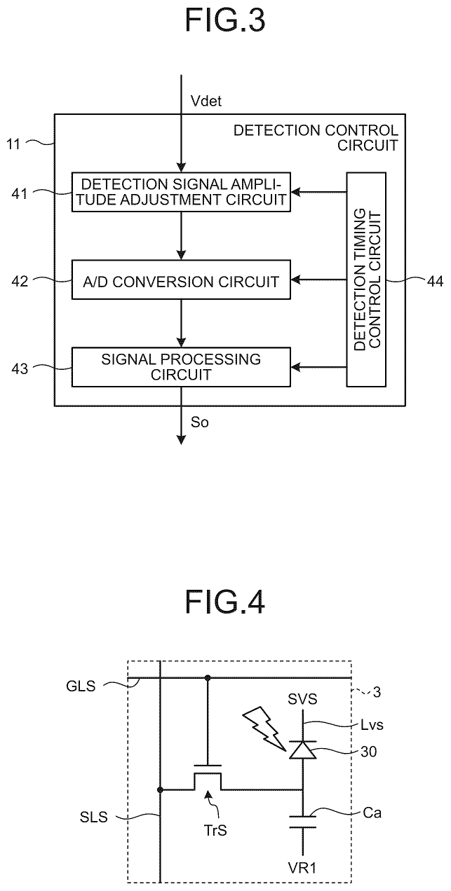

FIG. 3 is a block diagram illustrating a configuration example of the detection control circuit according to the first embodiment. As illustrated in FIG. 3, the detection control circuit 11 includes a detection signal amplitude adjustment circuit 41, an analog-to-digital (A/D) conversion circuit 42, a signal processing circuit 43, and a detection timing control circuit 44. Based on a control signal supplied from the host IC 70 (refer to FIG. 2), the detection timing control circuit 44 controls the detection signal amplitude adjustment circuit 41, the A/D conversion circuit 42, and the signal processing circuit 43 so as to operate synchronously.

The detection signal amplitude adjustment circuit 41 is a circuit that adjusts the amplitude of the detection signal Vdet output from the photodiode 30 and is configured with an amplifier, for example. The A/D conversion circuit 42 converts analog signals output from the detection signal amplitude adjustment circuit 41 into digital signals. The signal processing circuit 43 is a circuit that performs signal processing of the digital signals from the A/D conversion circuit 42 and transmits the sensor values So to the host IC 70.

Referring back to FIG. 2, the liquid crystal panel 50 includes an array substrate SUB1, the pixels Pix formed on the array substrate SUB1, gate line drive circuits 15C and 15D, a signal line drive circuit 16B, and a pixel control circuit (DDIC) 12.

The array substrate SUB1 is formed using a first insulating substrate 51 as a base. The pixels Pix are arranged in a matrix having a row-column configuration in an area of the array substrate SUB1 overlapping the detection area AA. The array substrate SUB1 is a drive circuit board for driving a liquid crystal layer LC (refer to FIG. 8) for each of the pixels Pix.

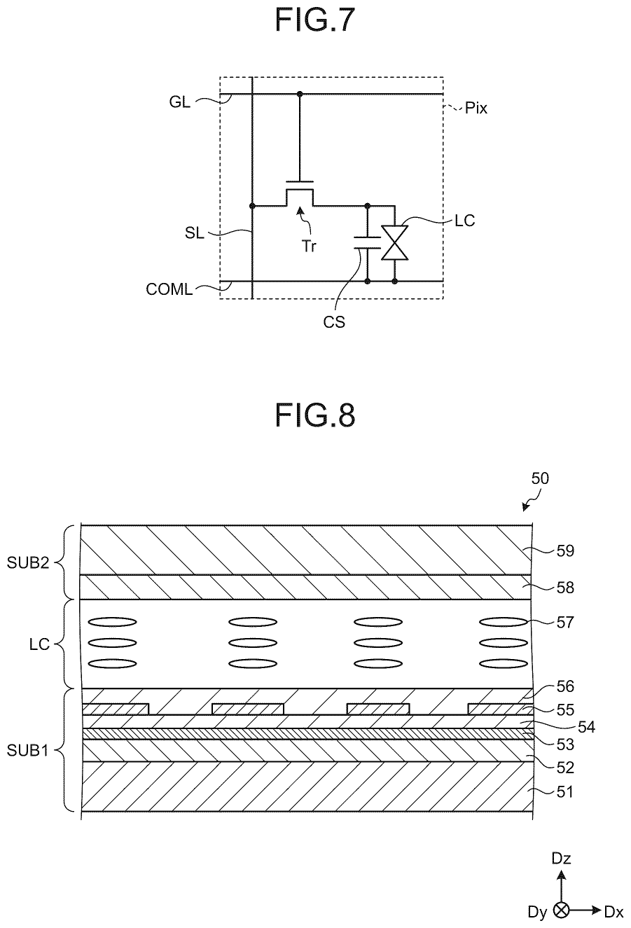

The pixel control circuit 12 is a circuit that supplies control signals Sd, Se, and Sf to the gate line drive circuits 15C and 15D, and the signal line drive circuit 16B, respectively, to control operations of these circuits. Specifically, the gate line drive circuits 15C and 15D output drive signals to gate lines GL (refer to FIG. 7) based on the control signals Sd and Se. The signal line drive circuit 16B supplies a pixel control signal to a signal line SL selected based on the control signal Sf. As a result, the liquid crystal panel 50 is controlled to be on (transmitting state of light) or off (non-transmitting state of light) for each of the pixels Pix.

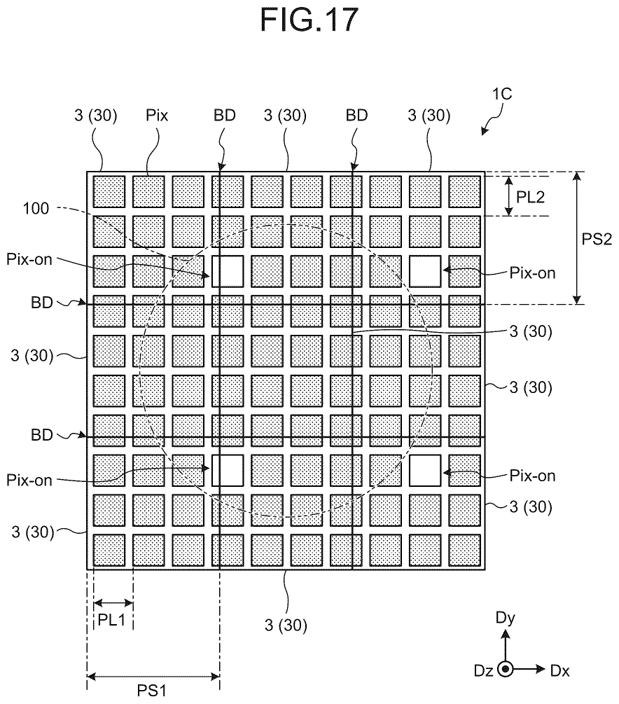

The host IC 70 includes a sensor value storage circuit 71, a sensitivity map storage circuit 72, and an adjustment value generation circuit 73 as control circuits for the optical sensor 10. The sensor value storage circuit 71 is a circuit that stores therein the sensor values So output from the detection control circuit 11 of the optical sensor 10. The sensitivity map storage circuit 72 is a circuit that stores therein a distribution of detection sensitivity of the photodiodes 30 when the object to be detected 100 is not present in the detection area AA, as a sensitivity map. The adjustment value generation circuit 73 is a circuit that generates adjustment values for gradations of a combined image based on the sensitivity map. The sensitivity map storage circuit 72 and the adjustment value generation circuit 73 will be described in detail in a third embodiment (FIGS. 17 to 19).

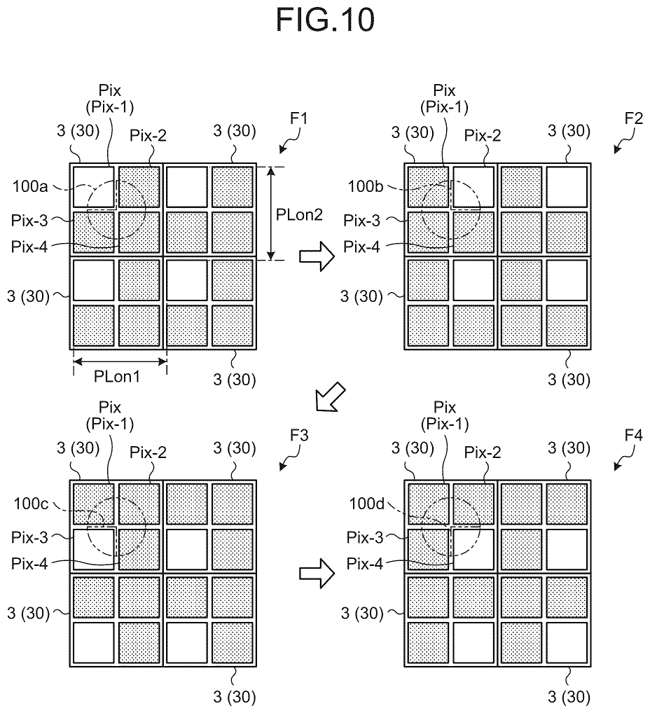

The host IC 70 includes an image generation circuit 74 and an image storage circuit 75 and is provided as control circuits for the liquid crystal panel 50. The image storage circuit 75 is a circuit that stores therein information on an arrangement pattern of on (transmitting state of light) and off (non-transmitting state of light) of the pixels Pix for each detection period F (refer to FIG. 10). The image generation circuit 74 is a circuit that generates the pixel control signals based on the information on the arrangement pattern in the image storage circuit 75. The image generation circuit 74 outputs the pixel control signals including the information on the arrangement pattern of on and off of the pixels Pix to the signal line drive circuit 16B in each of the detection periods F.

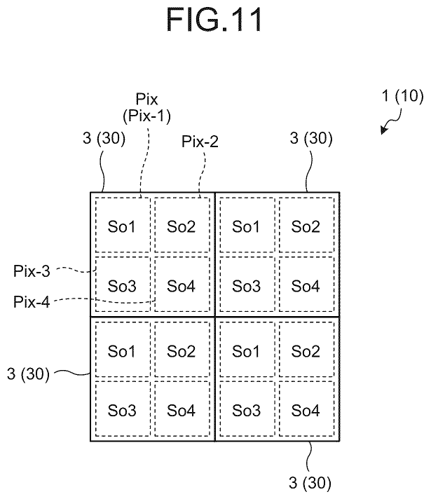

The host IC 70 further includes a combined image generation circuit 76. The combined image generation circuit 76 is a circuit that generates one combined image by combining images of the detection periods F (refer to FIG. 10) based on the sensor values So from the sensor value storage circuit 71 and the information on the arrangement pattern from the image storage circuit 75. A detailed operation example of the combined image generation circuit 76 will be described later with reference to FIGS. 10 and 11.

While not illustrated, the host IC 70 includes a control circuit that synchronously controls the detection control circuit 11 and the pixel control circuit 12. That is, the switching of the arrangement pattern of on and off of the pixels Pix of the liquid crystal panel 50 and the detection by the photodiodes 30 of the optical sensor 10 are synchronously controlled based on a control signal from the host IC 70. The optical sensor 10 includes the two gate line drive circuits 15A and 15B but may include one gate line drive circuit. The liquid crystal panel 50 includes the two gate line drive circuits 15C and 15D but may include one gate line drive circuit.

The following describes a configuration example of the optical sensor 10. FIG. 4 is a circuit diagram illustrating the sensor pixel. As illustrated in FIG. 4, the sensor pixel 3 includes the photodiode 30, a capacitive element Ca, and a first transistor TrS. The first transistor TrS is provided correspondingly to the photodiode 30. The first transistor TrS is configured as a thin-film transistor, and in this example, configured as an n-channel metal oxide semiconductor (MOS) thin-film transistor (TFT). The gate of the first transistor TrS is coupled to the sensor gate line GLS. The source of the first transistor TrS is coupled to the sensor signal line SLS. The drain of the first transistor Trs is coupled to the anode of the photodiode 30 and the capacitive element Ca.

The cathode of the photodiode 30 is supplied with a power supply potential SVS from the detection control circuit 11. The capacitive element Ca is supplied with a reference potential VR1 serving as an initial potential of the capacitive element Ca from the detection control circuit 11.

When the sensor pixel 3 is irradiated with light, a current corresponding to the amount of the light flows through the photodiode 30. As a result, an electric charge is stored in the capacitive element Ca. Turning on the first transistor TrS causes a current corresponding to the electric charge stored in the capacitive element Ca to flow through the sensor signal line SLS. The sensor signal line SLS is coupled to the detection control circuit 11 via the signal line drive circuit 16A. Thus, the optical sensor 10 of the detection device 1 can detect a signal corresponding to the amount of the light received by the photodiode 30 for each of the sensor pixels 3.

The first transistor Trs is not limited to the n-type TFT, and may be configured as a p-type TFT. The pixel circuit of the sensor pixel 3 illustrated in FIG. 4 is merely exemplary. The sensor pixel 3 may be provided with a plurality of transistors corresponding to one photodiode 30.

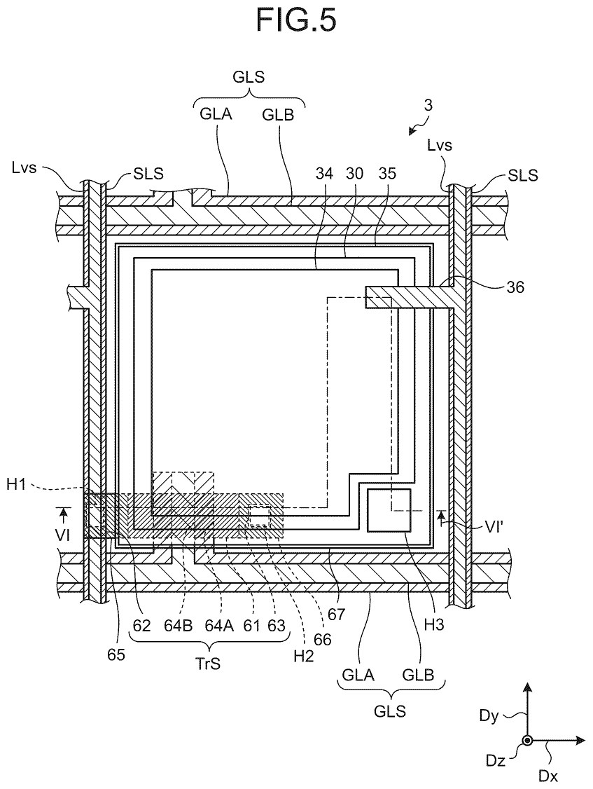

The following describes a detailed configuration of the optical sensor 10. FIG. 5 is a plan view schematically illustrating the sensor pixel according to the first embodiment.

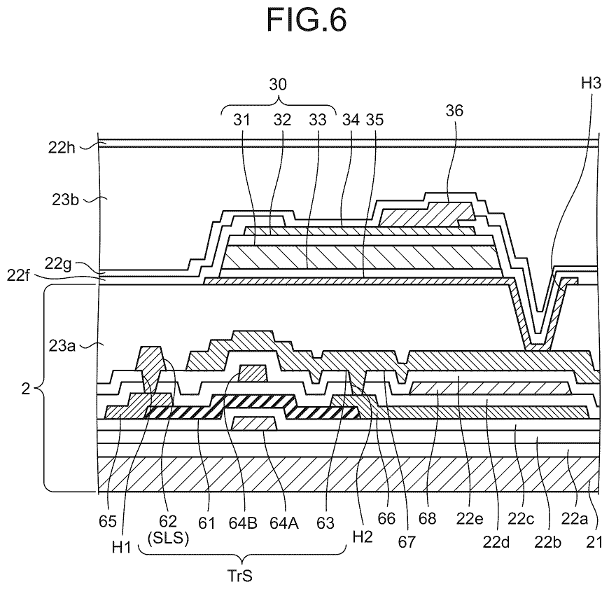

In the following description, a first direction Dx is one direction in a plane parallel to the substrate 21 (refer to FIG. 6). A second direction Dy is one direction in the plane parallel to the substrate 21 and is a direction orthogonal to the first direction Dx. The second direction Dy may non-orthogonally intersect the first direction Dx. A third direction Dz is a direction orthogonal to the first direction Dx and the second direction Dy and is a direction normal to a principal surface of the substrate 21. The term “plan view” refers to a positional relation when viewed in a direction orthogonal to the substrate 21.

As illustrated in FIG. 5, the sensor pixel 3 is an area surrounded by the sensor gate lines GLS and the sensor signal lines SLS. In the present embodiment, the sensor gate line GLS includes a first sensor gate line GLA and a second sensor gate line GLB. The first sensor gate line GLA is provided so as to overlap the second sensor gate line GLB. The first and the second sensor gate lines GLA and GLB are provided in different layers with insulating layers 22c and 22d (refer to FIG. 6) interposed therebetween. The first and the second sensor gate lines GLA and GLB are electrically coupled together at any point, and are supplied with the gate drive signals having the same potential. At least one of the first sensor gate line GLA and the second sensor gate line GLB is coupled to the gate line drive circuits 15A and 15B. In FIG. 5, the first and the second sensor gate lines GLA and GLB have different widths but may have the same width.

The photodiode 30 is provided in the area surrounded by the sensor gate lines GLS and the sensor signal lines SLS. An upper electrode 34 and a lower electrode 35 are provided for each of the photodiodes 30. The photodiode 30 is a PIN photodiode, for example. The lower electrode 35 is, for example, an anode electrode of the photodiode 30. The upper electrode 34 is, for example, a cathode electrode of the photodiode 30.

The upper electrode 34 is coupled to a power supply signal line Lvs through coupling wiring 36. The power supply signal line Lvs is wiring that supplies the power supply potential SVS to the photodiode 30. In the present embodiment, the power supply signal line Lvs extends in the second direction Dy while overlapping the sensor signal line SLS. The sensor pixels 3 arranged in the second direction Dy are coupled to the power supply signal line Lvs that is shared by those sensor pixels 3. Such a configuration can enlarge an opening for the sensor pixel 3. The lower electrode 35, the photodiode 30, and the upper electrode 34 are substantially quadrilateral in plan view. However, the shapes of the lower electrode 35, the photodiode 30, and the upper electrode 34 are not limited thereto, and can be modified as appropriate.

The first transistor TrS is provided near an intersection between the sensor gate line GLS and the sensor signal line SLS. The first transistor TrS includes a semiconductor layer 61, a source electrode 62, a drain electrode 63, a first gate electrode 64A, and a second gate electrode 64B.

The semiconductor layer 61 is an oxide semiconductor. The semiconductor layer 61 is more preferably a transparent amorphous oxide semiconductor (TAOS) among types of the oxide semiconductors. Using an oxide semiconductor as the first transistor TrS can reduce leakage currents of the first transistor TrS. That is, the first transistor Trs can reduce the leakage currents from the sensor pixel 3 that is not selected. Therefore, the optical sensor 10 can improve the signal-to-noise ratio (S/N). The semiconductor layer 61 is, however, not limited thereto, and may be formed of, for example, a microcrystalline oxide semiconductor, an amorphous oxide semiconductor, polysilicon, or low-temperature polycrystalline silicon (LTPS).

The semiconductor layer 61 is provided along the first direction Dx and intersects the first and the second gate electrodes 64A and 64B in plan view. The first and the second gate electrodes 64A and 64B are provided so as to branch from the first and the second sensor gate lines GLA and GLB, respectively. In other words, portions of the first and the second sensor gate lines GLA and GLB that overlap the semiconductor layer 61 serve as the first and the second gate electrodes 64A and 64B. Aluminum (Al), copper (Cu), silver (Ag), molybdenum (Mo), or an alloy of these metals is used as the first and the second gate electrodes 64A and 64B. Channel regions are formed at portions of the semiconductor layer 61 that overlap the first and the second gate electrodes 64A and 64B.

One end of the semiconductor layer 61 is coupled to the source electrode 62 through a contact hole H1. The other end of the semiconductor layer 61 is coupled to the drain electrode 63 through a contact hole H2. A portion of the sensor signal line SLS that overlaps the semiconductor layer 61 serves as the source electrode 62. A portion of a third conductive layer 67 that overlaps the semiconductor layer 61 serves as the drain electrode 63. The third conductive layer 67 is coupled to the lower electrode 35 through a contact hole H3. Such a configuration allows the first transistor TrS to switch between coupling and decoupling between the photodiode 30 and the sensor signal line SLS.

The following describes a layer configuration of the optical sensor 10. FIG. 6 is a sectional view taken along VI-VI′ in FIG. 5.

In the description of the detection device 1 that includes the optical sensor 10, a direction from the substrate 21 toward the photodiode 30 in a direction (third direction Dz) orthogonal to a surface of the substrate 21 is referred to as “upper side” or “above”. A direction from the photodiode 30 toward the substrate 21 is referred to as “lower side” or “below”.

The substrate 21 illustrated in FIG. 6 is an insulating substrate and is made using, for example, a glass substrate of quartz, alkali-free glass, or the like. The first transistors TrS, various types of wiring (sensor gate lines GLS and sensor signal lines SLS), and insulating layers are provided on one surface side of the substrate 21 to form the array substrate 2. The photodiodes 30 are arranged on the array substrate 2, that is, on the one surface side of the substrate 21. The substrate 21 may be a resin substrate or a resin film made of a resin such as polyimide.

Insulating layers 22a and 22b are provided on the substrate 21. Insulating layers 22a, 22b, 22c, 22d, 22e, 22f, and 22g are inorganic insulating films and are formed of silicon oxide (SiO₂) or silicon nitride (SiN). Each of the inorganic insulating layers is not limited to a single layer and may be a multilayered film.

The first gate electrode 64A is provided above the insulating layer 22b. The insulating layer 22c is provided on the insulating layer 22b so as to cover the first gate electrode 64A. The semiconductor layer 61, a first conductive layer 65, and a second conductive layer 66 are provided on the insulating layer 22c. The first conductive layer 65 is provided so as to cover an end of the semiconductor layer 61 coupled to the source electrode 62. The second conductive layer 66 is provided so as to cover an end of the semiconductor layer 61 coupled to the drain electrode 63.

The insulating layer 22d is provided on the insulating layer 22c so as to cover the semiconductor layer 61, the first conductive layer 65, and the second conductive layer 66. The second gate electrode 64B is provided on the insulating layer 22d. The semiconductor layer 61 is provided between the first gate electrode 64A and the second gate electrode 64B in the direction orthogonal to the substrate 21. That is, the first transistor TrS has what is called a dual-gate structure. The first transistor TrS may, however, have a bottom-gate structure that is provided with the first gate electrode 64A and not provided with the second gate electrode 64B, or a top-gate structure that is not provided with the first gate electrode 64A and provided with only the second gate electrode 64B.

The insulating layer 22e is provided on the insulating layer 22d so as to cover the second gate electrode 64B. The source electrode 62 (sensor signal line SLS) and the drain electrode 63 (third conductive layer 67) are provided on the insulating layer 22e. In the present embodiment, the drain electrode 63 is the third conductive layer 67 provided above the semiconductor layer 61 with the insulating layers 22d and 22e interposed therebetween. The source electrode 62 is electrically coupled to the semiconductor layer 61 through the contact hole H1 and the first conductive layer 65. The drain electrode 63 is electrically coupled to the semiconductor layer 61 through the contact hole H2 and the second conductive layer 66.

The third conductive layer 67 is provided in an area overlapping the photodiode 30 in plan view. The third conductive layer 67 is provided also on the upper side of the semiconductor layer 61 and the first and the second gate electrodes 64A and 64B. That is, the third conductive layer 67 is provided between the second gate electrode 64B and the lower electrode 35 in the direction orthogonal to the substrate 21. With this configuration, the third conductive layer 67 has a function as a protective layer that protects the first transistor TrS.

The second conductive layer 66 extends so as to face the third conductive layer 67 in an area not overlapping the semiconductor layer 61. A fourth conductive layer 68 is provided on the insulating layer 22d in the area not overlapping the semiconductor layer 61 The fourth conductive layer 68 is provided between the second conductive layer 66 and the third conductive layer 67. This configuration generates capacitance between the second conductive layer 66 and the fourth conductive layer 68, and capacitance between the third conductive layer 67 and the fourth conductive layer 68. The capacitance generated by the second conductive layer 66, the third conductive layer 67, and the fourth conductive layer 68 serves as capacitance of the capacitive element Ca illustrated in FIG. 4.

A first organic insulating layer 23a is provided on the insulating layer 22e so as to cover the source electrode 62 (sensor signal line SLS) and the drain electrode 63 (third conductive layer 67). The first organic insulating layer 23a is a planarizing layer that planarizes asperities formed by the first transistor Trs and various conductive layers.

The following describes a sectional configuration of the photodiode 30. In the photodiode 30, the lower electrode 35, the photodiode 30, and the upper electrode 34 are stacked in this order on the first organic insulating layer 23a of the array substrate 2.

The lower electrode 35 is provided on the first organic insulating layer 23a and is electrically coupled to the third conductive layer 67 through the contact hole H3. The lower electrode 35 is the anode of the photodiode 30 and is an electrode for reading the detection signal Vdet. For example, a metal material such as molybdenum (Mo) or aluminum (Al) is used as the lower electrode 35. The lower electrode 35 may alternatively be a multilayered film formed of a plurality of layers of these metal materials. The lower electrode 35 may be formed of a light-transmitting conductive material such as indium tin oxide (ITO) or indium zinc oxide (IZO).

The photodiode 30 includes an i-type semiconductor layer 31, an n-type semiconductor layer 32, and a p-type semiconductor layer 33 as semiconductor layers. The i-type semiconductor layer 31, the n-type semiconductor layer 32, and the p-type semiconductor layer 33 are formed of amorphous silicon (a-Si), for example. In FIG. 6, the p-type semiconductor layer 33, the i-type semiconductor layer 31, and the n-type semiconductor layer 32 are stacked in this order in the direction orthogonal to the surface of the substrate 21. However, the photodiode 30 may have a reversed configuration. That is, the n-type semiconductor layer 32, the i-type semiconductor layer 31, and the p-type semiconductor layer 33 may be stacked in this order. Each of the semiconductor layers may be a photoelectric conversion element formed of an organic semiconductor.

The a-Si of the n-type semiconductor layer 32 is doped with impurities to form an n+ region. The a-Si of the p-type semiconductor layer 33 is doped with impurities to form a p+ region. The i-type semiconductor layer 31 is, for example, a non-doped intrinsic semiconductor and has lower conductivity than that of the n-type semiconductor layer 32 and the p-type semiconductor layer 33.

The upper electrode 34 is the cathode of the photodiode 30 and is an electrode for supplying the power supply potential SVS to the photoelectric conversion layers. The upper electrode 34 is, for example, a light-transmitting conductive layer of, for example, ITO, and a plurality of the upper electrodes 34 are provided for the respective photodiodes 30.

The insulating layers 22f and 22g are provided on the first organic insulating layer 23a. The insulating layer 22f covers the periphery of the upper electrode 34 and is provided with an opening in a position overlapping the upper electrode 34. The coupling wiring 36 is coupled to a portion of the upper electrode 34 not provided with the insulating layer 22f. The insulating layer 22g is provided on the insulating layer 22f so as to cover the upper electrode 34 and the coupling wiring 36. A second organic insulating layer 23b serving as a planarizing layer is provided on the insulating layer 22g. In the case of the organic semiconductor photodiode 30, an insulating layer 22h may be further provided thereon.

The following describes a configuration example of the liquid crystal panel 50. FIG. 7 is a circuit diagram illustrating the pixel of the liquid crystal panel according to the first embodiment. As illustrated in FIG. 7, the pixel Pix includes a second transistor Tr and capacitance CS of the liquid crystal layer LC. The second transistor Tr is configured as a thin-film transistor, and in this example, configured as an n-channel MOS TFT.

One of the source electrode and the drain electrode of the second transistor Tr is coupled to the signal line SL; the gate electrode is coupled to the scan line GL; and the other of the source electrode and the drain electrode is coupled to one end of the capacitance CS of the liquid crystal layer LC to be described later. The one end of the capacitance CS of the liquid crystal layer LC is coupled to the second transistor Tr via a pixel electrode 55 (refer to FIG. 8), and the other end thereof is coupled to common potential wiring COML via a common electrode 53 (FIG. 8).

FIG. 8 is a sectional view schematically illustrating a configuration example of the liquid crystal panel according to the first embodiment. As illustrated in FIG. 8, the liquid crystal panel 50 includes, for example, the array substrate SUB1, a counter substrate SUB2, and the liquid crystal layer LC. The counter substrate SUB2 is disposed so as to face the array substrate SUB1. The liquid crystal layer LC is enclosed between the array substrate SUB1 and the counter substrate SUB2.

The array substrate SUB1 includes the first insulating substrate 51, a circuit forming layer 52, the common electrode 53, an insulating film 54, the pixel electrode 55, and a lower orientation film 56. The circuit forming layer 52, the common electrode 53, the insulating film 54, the pixel electrode 55, and the lower orientation film 56 are stacked in this order in the third direction Dz on the first insulating substrate 51.

The first insulating substrate 51 is a light-transmitting glass or film substrate. The circuit forming layer 52 is a layer in which the pixel circuit including the second transistor Tr of the pixel Pix illustrated in FIG. 7 and various types of wirings are formed. The common electrode 53 is an electrode that is supplied with a predetermined constant potential. The insulating film 54 insulates the common electrode 53 from the pixel electrode 55. The pixel electrode 55 is provided for each of the pixels Pix and is each individually controlled in potential. The lower orientation film 56 is provided so as to cover the pixel electrodes 55 and the insulating film 54.

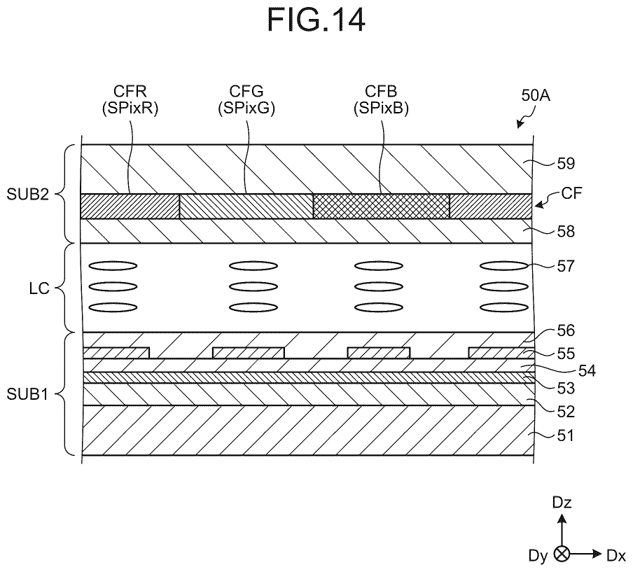

The counter substrate SUB2 includes a second insulating substrate 59 and an upper orientation film 58. The upper orientation film 58 is provided on a surface of the second insulating substrate 59 facing the first insulating substrate 51. The upper orientation film 58 serves as a surface on the liquid crystal layer LC side of the counter substrate SUB2. In the present embodiment, a color filter CF (refer to FIG. 14) is provided neither on the array substrate SUB1 nor on the counter substrate SUB2. That is, the liquid crystal panel 50 emits monochrome light toward the photodiode 30.

Although not illustrated in FIG. 8, optical elements including polarizing plates are provided on respective outer surfaces of the first insulating substrate 51 and the second insulating substrate 59. The polarizing axes of a pair of the polarizing plates are in a crossed nicols positional relation in plan view. The counter substrate SUB2 may be provided with a color filter or a light-blocking film, as required.

The liquid crystal layer LC modulates light passing therethrough according to the state of an electric field and uses, for example, liquid crystals in a horizontal electric field mode, such as in-plane switching (IPS) including fringe field switching (FFS). In the present embodiment, the liquid crystal layer LC is driven by the horizontal electric field generated between the pixel electrode 55 and the common electrode 53 provided on the array substrate, and the orientation of liquid crystal molecules 57 included in the liquid crystal layer LC is controlled.

However, the liquid crystal panel 50 is not limited to this configuration and may be a vertical electric field panel. In that case, the pixel electrode is provided on the array substrate SUB1 and the common electrode is provided on the counter substrate SUB2. Examples of the vertical electric field liquid crystal panel include, but are not limited to, a twisted nematic (TN) panel, a vertical alignment (VA) panel, and an electrically controlled birefringence (ECB) panel in which what is called a vertical electric field is applied to the liquid crystal layer.

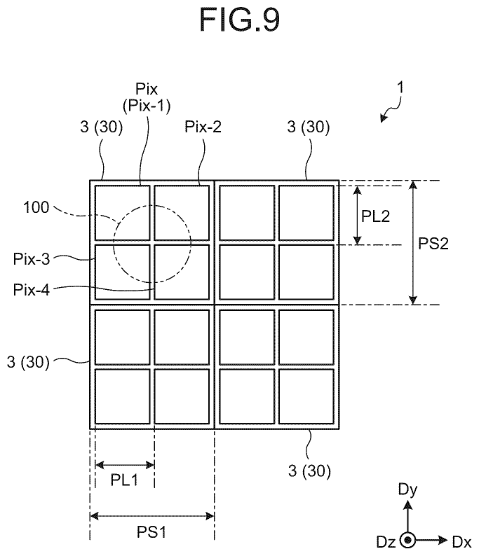

The following describes an arrangement relation between the liquid crystal panel 50 and the optical sensors 10 and an exemplary detection operation. FIG. 9 is a plan view schematically illustrating the arrangement relation between the pixels of the liquid crystal panel and the sensor pixels of the optical sensor in the detection device according to the first embodiment.

As illustrated in FIG. 9, one of the photodiodes 30 is disposed in a position overlapping more than one of the pixels Pix. In FIG. 9, one of the photodiodes 30 is disposed so as to overlap four of the pixels Pix. That is, in plan view, the size of the photodiode 30 is larger than that of each of the pixel Pix. In the present embodiment, the size of the photodiode 30 is the area of a region surrounded by the sensor gate lines GLS and the sensor signal lines SLS (refer to FIG. 5). In the same way, the size of the pixel Pix is the area of a region surrounded by the scan lines GL and the signal lines SL (refer to FIG. 7).

An arrangement pitch PL1 of the pixels Pix in the first direction Dx is smaller than an arrangement pitch PS1 of the photodiodes 30 in the first direction Dx. An arrangement pitch PL2 of the pixels Pix in the second direction Dy is smaller than an arrangement pitch PS2 of the photodiodes 30 in the second direction Dy. More preferably, the arrangement pitch PS1 of the photodiodes 30 in the first direction Dx is an integer multiple of the arrangement pitch PL1 of the pixels Pix in the first direction Dx. The arrangement pitch PS2 of the photodiodes 30 in the second direction Dy is an integer multiple of the arrangement pitch PL2 of the pixels Pix in the second direction Dy. In the example illustrated in FIG. 9, the arrangement pitches PS1 and PS2 of the photodiodes 30 are twice the arrangement pitches PL1 and PL2 of the pixels Pix.

The arrangement pitch PS1 of the photodiodes 30 in the first direction Dx is defined by the arrangement pitch of the sensor signal lines SLS in the first direction Dx. The arrangement pitch PS2 of the photodiodes 30 in the second direction Dy is defined by the arrangement pitch of the sensor gate lines GLS in the second direction Dy. The arrangement pitch PL1 of the pixels Pix in the first direction Dx is defined by the arrangement pitch of the signal lines SL in the first direction Dx. The arrangement pitch PL2 of the pixels Pix in the second direction Dy is defined by the arrangement pitch of the scan lines GL in the second direction Dy.

FIG. 9 illustrates the sensor pixels 3 (photodiodes 30) in two rows and two columns. The pixels Pix in two rows and two columns are arranged so as to overlap one of the photodiodes 30. In the following description, the pixels Pix overlapping one of the photodiodes 30 are denoted as a first pixel Pix-1, a second pixel Pix-2, a third pixel Pix-3, and a fourth pixel Pix-4. The first pixel Pix-1 and the second pixel Pix-2 are arranged adjacent to each other in the first direction Dx. The third pixel Pix-3 and the fourth pixel Pix-4 are arranged adjacent to each other in the first direction Dx. The first pixel Pix-1 and the second pixel Pix-2 arranged in the first direction Dx are adjacent to the third pixel Pix-3 and the fourth pixel Pix-4, respectively, in the second direction Dy. The first pixel Pix-1, the second pixel Pix-2, the third pixel Pix-3, and the fourth pixel Pix-4 are simply referred to as the pixel Pix when need not be distinguished from one another.

FIG. 10 is an explanatory diagram for explaining the exemplary detection operation of the detection device according to the first embodiment. FIG. 11 is an explanatory diagram for explaining a method for generating the combined image by the detection device according to the first embodiment. FIG. 10 illustrates the pixels Pix in the transmitting state by non-shaded areas (in white), and the pixels Pix in the non-transmitting state by shaded areas. FIG. 10 illustrates a case where the object to be detected 100 is disposed so as to overlap one of the photodiodes 30 that is disposed at the upper left corner. FIG. 11 illustrates the detection signals (sensor values So) output from the photodiode 30 in each of detection periods F1, F2, F3, and F4 correspondingly to the pixel Pix in the transmitting state in each of the detection periods F.

In the following description, the detection periods F1, F2, F3, and F4 will each be simply referred to as the detection period F when need not be distinguished from one another. A first sensor value So1, a second sensor value So2, a third sensor value So3, and a fourth sensor value So4 will each be simply referred to as the sensor value So when need not be distinguished from one another.

As illustrated in FIG. 10, the liquid crystal panel 50 brings at least one of the pixels Pix overlapping the photodiode 30 into the transmitting state and brings the other pixels Pix into the non-transmitting state. The photodiode 30 of each of the sensor pixels 3 detects the object to be detected 100 based on the light that has been emitted from the light source 80 and transmitted through the pixel Pix in the transmitting state. In other words, the light emitted from the light source 80 is blocked at a portion of the photodiode 30 that overlaps the pixel Pix in the non-transmitting state, and the object to be detected 100 is not detected.

The liquid crystal panel 50 sequentially scans the pixel Pix in the transmitting state among the pixels Pix overlapping the photodiode 30 in each of the predetermined detection periods F1, F2, F3, and F4. That is, the liquid crystal panel 50 changes the arrangement pattern of the pixels Pix in the transmitting state and the pixels Pix in the non-transmitting state among the pixels Pix overlapping the photodiode 30, for each of the detection periods F1, F2, F3, and F4. The photodiode 30 sequentially outputs the detection signal Vdet (sensor value So) corresponding to the light transmitted through the pixel Pix in the transmitting state in each of the detection periods F1, F2, F3, and F4.

Specifically, during the detection period F1, the liquid crystal panel 50 brings the first pixel Pix-1 among the pixels Pix overlapping the photodiode 30 into the transmitting state and brings the second pixel Pix-2, the third pixel Pix-3, and the fourth pixel Pix-4 into the non-transmitting state. In the detection period F1, the photodiode 30 outputs the detection signal (first sensor value So1) corresponding to the light transmitted through the first pixel Pix-1 in the transmitting state. During the detection period F1 in FIG. 10, for the one of the photodiodes 30 disposed at the upper left corner, the light from the light source 80 is transmitted through a portion of the object to be detected 100 that overlaps the first pixel Pix-1 in the transmitting state. In the detection period F1, the photodiode 30 detects the portion of the object to be detected 100 that overlaps the first pixel Pix-1.

During the next detection period F2, the liquid crystal panel 50 brings the second pixel Pix-2 of the pixels Pix overlapping the photodiode 30 into the transmitting state, and brings the first pixel Pix-1, the third pixel Pix-3, and the fourth pixel Pix-4 into the non-transmitting state. In the detection period F2, the photodiode 30 outputs the detection signal (second sensor value So2) corresponding to the light transmitted through the second pixel Pix-2 in the transmitting state. In the detection period F2 in FIG. 10, for the one of the photodiodes 30 disposed at the upper left corner, the light from the light source 80 is transmitted through a portion of the object to be detected 100 that overlaps the second pixel Pix-2 in the transmitting state. During the detection period F2, the photodiode 30 detects the portion of the object to be detected 100 that overlaps the second pixel Pix-2.

During the next detection period F3, the liquid crystal panel 50 brings the third pixel Pix-3 of the pixels Pix overlapping the photodiode 30 into the transmitting state, and brings the first pixel Pix-1, the second pixel Pix-2, the fourth pixel Pix-4 into the non-transmitting state. During the detection period F3, the photodiode 30 outputs the detection signal (third sensor value So3) corresponding to the light transmitted through the third pixel Pix-3 in the transmitting state. In the detection period F3 in FIG. 10, for the one of the photodiodes 30 disposed at the upper left corner, the light from the light source 80 is transmitted through a portion of the object to be detected 100 that overlaps the third pixel Pix-3 in the transmitting state. In the detection period F3, the photodiode 30 detects the portion of the object to be detected 100 that overlaps the third pixel Pix-3.

During the next detection period F4, the liquid crystal panel 50 brings the fourth pixel Pix-4 of the pixels Pix overlapping the photodiode 30 into the transmitting state, and brings the first pixel Pix-1, the second pixel Pix-2, the third pixel Pix-3 into the non-transmitting state. In the detection period F4, the photodiode 30 outputs the detection signal (fourth sensor value So4) corresponding to the light transmitted through the fourth pixel Pix-4 in the transmitting state. In the detection period F4 in FIG. 10, for the one of the photodiodes 30 disposed at the upper left corner, the light from the light source 80 is transmitted through a portion of the object to be detected 100 that overlaps the fourth pixel Pix-4 in the transmitting state. During the detection period F4, the photodiode 30 detects the portion of the object to be detected 100 that overlaps the fourth pixel Pix-4.

In the detection device 1 according to the present embodiment, for example, even when the object to be detected 100 is the microscopic objects and has a smaller size than the arrangement pitches PS1 and PS2 of the photodiodes 30 as illustrated in FIG. 10, it is possible, by scanning the pixel Pix in the transmitting state, for one of the photodiodes 30 to detect information on each portion of the object to be detected 100 overlapping the pixel Pix in the transmitting state. In the example illustrated in FIG. 10, four detection signals (sensor values So) are output from one of the photodiodes 30.

The sensor value storage circuit 71 (refer to FIG. 2) of the host IC 70 stores therein the first sensor value So1, the second sensor value So2, the third sensor value So3, and the fourth sensor value So4 output from the photodiodes 30 in each of the detection periods F1, F2, F3, and F4. The combined image generation circuit 76 (refer to FIG. 2) acquires information on each of the sensor values So in each of the detection periods F1, F2, F3, and F4 from the sensor value storage circuit 71. The combined image generation circuit 76 acquires, from the image storage circuit 75, the information on the arrangement pattern of the pixels Pix in the transmitting state and the pixels Pix in the non-transmitting state in each of the detection periods F1, F2, F3, and F4.

As illustrated in FIG. 11, the combined image generation circuit 76 integrates the sensor values So based on the detection signals (the first sensor value So1, the second sensor value So2, the third sensor value So3, and the fourth sensor value So4) in each of the detection periods F1, F2, F3, and F4 and information (positional information) on the pixels Pix in the transmitting state in each of the detection periods F1, F2, F3, and F4. The combined image generation circuit 76 thereby combines images in the detection periods F1, F2, F3, and F4 to generate one combined image.

As described above, the detection device 1 can increase the substantial resolution of the optical sensor 10 to a level equal to or finer than the arrangement pitches PS1 and PS2 of the photodiodes 30 by scanning the pixels Pix in the transmitting state in each of the detection periods F and generating the combined image by integrating the sensor values So for each of the detection periods F. The substantial resolution of the generated combined image can be increased to substantially the same level as the arrangement pitches PL1 and PL2 of the pixels Pix of the liquid crystal panel 50.

As illustrated in FIG. 10, for example, in the first pixel row, the liquid crystal panel 50 alternately arranges the pixel Pix in the transmitting state and the pixel Pix in the non-transmitting state in the first direction Dx. An arrangement pitch PLon1 of the pixels Pix in the transmitting state in the first direction Dx is equal to or larger than the arrangement pitch PS1 of the photodiodes 30 in the first direction Dx. In the same way, the liquid crystal panel 50 alternately arranges the pixel Pix in the transmitting state and the pixel Pix in the non-transmitting state in the second direction Dy in the leftmost pixel column. An arrangement pitch PLon2 of the pixels Pix in the transmitting state in the second direction Dy is equal to or larger than the arrangement pitch PS2 of the photodiodes 30 in the second direction Dy.

This arrangement pattern of the pixels Pix in the transmitting state and the pixels Pix in the non-transmitting state prevents two or more of the pixels Pix in the transmitting state from being arranged adjacent to each other in an area overlapping one photodiode 30. This configuration allows the detection device 1 to well improve the substantial resolution of the optical sensor 10.

As described above, the light source 80 (refer to FIG. 1) emits the parallel light toward the liquid crystal panel 50. As a result, the light transmitted through the pixels Pix in the transmitting state passes through portions of the object to be detected 100 that overlap the pixels Pix in the transmitting state and enters the photodiodes 30 that overlap the pixels Pix in the transmitting state. That is, compared with a case where light in oblique directions enters the pixels Pix in the transmitting state, the light transmitted through the pixels Pix in the transmitting state can be restrained from passing through portions of the object to be detected 100 that do not overlap the pixels Pix in the transmitting state, or can be restrained from entering the other photodiodes 30 adjacent to the photodiodes 30 that overlap the pixels Pix in the transmitting state. Therefore, the detection device 1 can restrain images from blurring.

In FIG. 10, the arrangement pattern of the pixels Pix in the transmitting state and the pixels Pix in the non-transmitting state in one detection period F is the same in each of the photodiodes 30. However, the present disclosure is not limited to this configuration, and the arrangement pattern may differ among the photodiodes 30. In one photodiode 30, the pixels Pix in the transmitting state may be scanned in any order in each of the detection periods F.

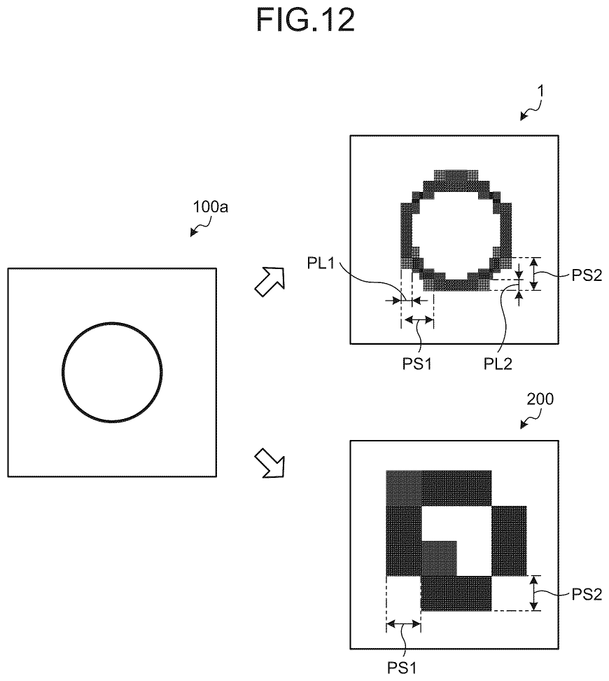

FIG. 12 is a diagram illustrating simulation results of detected images in detection devices according to an example and a comparative example. FIG. 12 illustrates the simulation results of the detection device 1 according to the example and a detection device 200 according to the comparative example in both of which the same object to be detected 100a having an annular shape is detected.

The detection device 200 according to the comparative example is configured without the liquid crystal panel 50. As illustrated in FIG. 9, in the detection device 200 according to the comparative example, the shape of the object to be detected 100a is difficult to be determined because the resolution of the image is lower with respect to the object to be detected 100a. In the detection device 200 according to the comparative example, the resolution of the detected image is defined by the arrangement pitches PS1 and PS2 of the photodiodes 30.

In the detection device 200 according to the comparative example, for example, when the object to be detected 100 is the microscopic objects and has a smaller size than the arrangement pitches PS1 and PS2 of the photodiodes 30 as illustrated in FIG. 9, one detection signal (sensor value So) is output from one photodiode 30. That is, the detection device 200 of the comparative example may be capable of detecting only presence or absence of the object to be detected 100, which is the microscopic objects, and difficult to detect the external shape.

In contrast, the detection device 1 according to the embodiment has a configuration in which the photodiodes 30 are combined with the liquid crystal panel 50. The arrangement pitches PL1 and PL2 of the pixels Pix are approximately ¼ the arrangement pitches PS1 and PS2 of the photodiodes 30. As illustrated in FIG. 12, the detection device 1 according to the example has improved resolution as compared with the detection device 200 of the comparative example, and detects an annular image similar to the object to be detected 100a. The detection device 1 according to the example has proved to improve the substantial resolution of the generated combined image to substantially the same level as the arrangement pitches PL1 and PL2 of the pixels Pix.

The photodiodes 30 and the pixels Pix illustrated in FIGS. 9 to 11 are schematically illustrated for ease of understanding, and the shapes, numbers, and arrangement relation of the photodiodes 30 and the pixels Pix can be changed as appropriate. For example, the number of the pixels Pix overlapping one of the photodiode 30 may be two or three, or even five or more. The configuration of the optical sensor 10 including the photodiodes 30 has been described, but the configuration is not limited to this configuration. The optical sensor 10 only needs to include at least one photodiode 30, and the detection device 1 may be provided with the pixels Pix of the liquid crystal panel 50 overlapping one photodiode 30.

### Second Embodiment

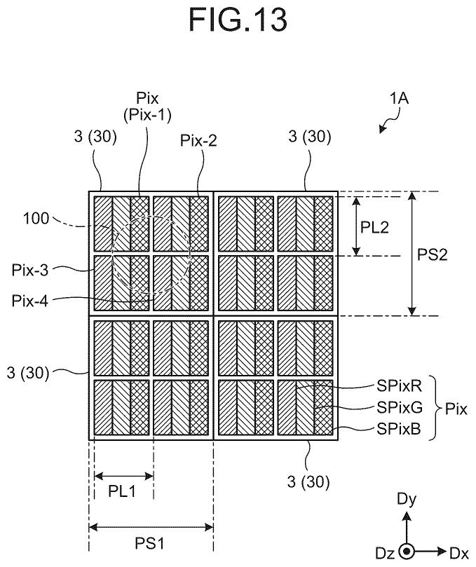

FIG. 13 is a plan view schematically illustrating an arrangement relation between the pixels of a liquid crystal panel and the sensor pixels of the optical sensor in a detection device according to a second embodiment. FIG. 14 is a sectional view schematically illustrating a configuration example of the liquid crystal panel according to the second embodiment. In the following description, the same components as those described in the embodiment described above are denoted by the same reference numerals, and the description thereof will not be repeated.

As illustrated in FIG. 13, in a detection device 1A according to the second embodiment, each of the pixels Pix includes a first sub-pixel SPixR, a second sub-pixel SPixG, and a third sub-pixel SPixB. In FIG. 13, one photodiode 30 is disposed so as to overlap four pixels Pix, that is, 12 sub-pixels SPix.

The first sub-pixel SPixR, the second sub-pixel SPixG, and the third sub-pixel SPixB are arranged in this order in the first direction Dx. The first sub-pixel SPixR includes a first-color color filter CFR (refer to FIG. 14) and emits red (R) light. The second sub-pixel SPixG includes a second-color color filter CFG (refer to FIG. 14) and emits green (G) light. The third sub-pixel SPixB includes a third-color color filter CFB (refer to FIG. 14) and emits blue (B) light.

As illustrated in FIG. 14, the counter substrate SUB2 of a liquid crystal panel 50A according to the second embodiment includes the color filter CF. The color filter CF is provided on the surface of the second insulating substrate 59 facing the first insulating substrate 51. The upper orientation film 58 is provided so as to cover the color filter CF. The color filter CF includes the first-color color filter CFR, the second-color color filter CFG, and the third-color color filter CFB, which are periodically arranged to provide color regions colored in red (R), green (G), and blue (B), respectively.

The color filter CF may have color regions of four or more colors. In that case, the pixel Pix may include four or more sub-pixels SPix.

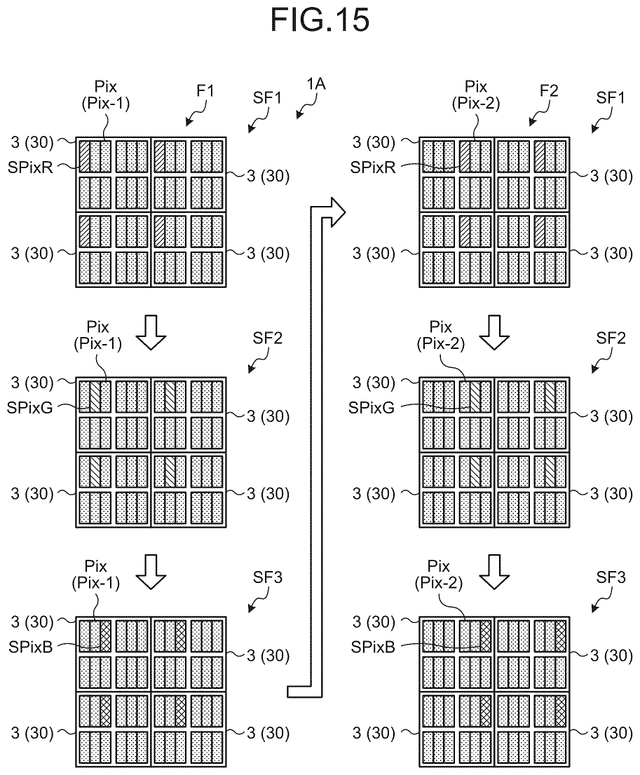

FIG. 15 is an explanatory diagram for explaining an exemplary detection operation of the detection device according to the second embodiment. FIG. 15 illustrates an example of scanning the sub-pixels SPix in the transmitting state for the first pixel Pix-1 and the second pixel Pix-2, and omits illustration for the third pixel Pix-3 and the fourth pixel Pix-4.

As illustrated in FIG. 15, the liquid crystal panel 50A brings one sub-pixel SPix of the pixels Pix overlapping one of the photodiodes 30 into the transmitting state, and brings the other sub-pixels SPix into the non-transmitting state.

Specifically, in a detection period SF1 (first period), the liquid crystal panel 50A brings the first sub-pixel SPixR of the first pixel Pix-1 into the transmitting state, and brings the second sub-pixel SPixG and the third sub-pixel SPixB of the first pixel Pix-1, and the second pixel Pix-2, the third pixel Pix-3, and the fourth pixel Pix-4 into the non-transmitting state, among the pixels Pix overlapping the photodiode 30. In the detection period SF1, the photodiode 30 outputs the detection signal (first sensor value Sol) corresponding to the light transmitted through the first sub-pixel SPixR of the first pixel Pix-1 in the transmitting state.

In a detection period SF2 (second period), the liquid crystal panel 50A brings the second sub-pixel SPixG of the first pixel Pix-1 into the transmitting state, and brings the first sub-pixel SPixR and the third sub-pixel SPixB of the first pixel Pix-1, and the second pixel Pix-2, the third pixel Pix-3, and the fourth pixel Pix-4 into the non-transmitting state, among the pixels Pix overlapping the photodiode 30. In the detection period SF2, the photodiode 30 outputs the detection signal (second sensor value So2) corresponding to the light transmitted through the second sub-pixel SPixG of the first pixel Pix-1 in the transmitting state.

In a detection period SF3 (third period), the liquid crystal panel 50A brings the third sub-pixel SPixB of the first pixel Pix-1 into the transmitting state, and brings the first sub-pixel SPixR and the second sub-pixel SPixG of the first pixel Pix-1, and the second pixel Pix-2, the third pixel Pix-3, and the fourth pixel Pix-4 into the non-transmitting state, among the pixels Pix overlapping the photodiode 30. In the detection period SF3, the photodiode 30 outputs the detection signal (third sensor value So3) corresponding to the light transmitted through the third sub-pixel SPixB of the first pixel Pix-1 in the transmitting state.

Thereafter, the detection periods SF1, SF2, and SF3 are repeated for each of the sub-pixels SPix of the second pixel Pix-2, the third pixel Pix-3, and the fourth pixel Pix-4. That is, the first sub-pixel SPixR, the second sub-pixel SPixG, and the third sub-pixel SPixB are sequentially brought into the transmitting state in a time-division manner in the second pixel Pix-2. Then, the first sub-pixel SPixR, the second sub-pixel SPixG, and the third sub-pixel SPixB are sequentially brought into the transmitting state in a time-division manner in the third pixel Pix-3. Then, the first sub-pixel SPixR, the second sub-pixel SPixG, and the third sub-pixel SPixB are sequentially brought into the transmitting state in a time-division manner in the fourth pixel Pix-4.

The combined image generation circuit 76 (illustrated in FIG. 2) acquires information on each of the sensor values So in each of the detection periods SF1, SF2, and SF3 from the sensor value storage circuit 71. In the example illustrated in FIG. 15, the combined image generation circuit 76 acquires information on 12 sensor values So per photodiode 30. The combined image generation circuit 76 acquires, from the image storage circuit 75, a total of 12 pieces of information on the arrangement pattern of the sub-pixels SPix in the transmitting state and the sub-pixels SPix in the non-transmitting state in each of the detection periods SF1, SF2, and SF3.

The combined image generation circuit 76 acquires information on a red image based on the first sensor values So1 in a plurality of the detection periods SF1. The combined image generation circuit 76 acquires information on a green image based on the second sensor values So2 in a plurality of the detection periods SF2. The combined image generation circuit 76 acquires information on a blue image based on the third sensor values So3 in a plurality of the detection periods SF3. The combined image generation circuit 76 combines the images in the detection periods SF1, SF2, and SF3 to generate a color image as one combined image.

As described above, the detection device 1A according to the second embodiment changes the arrangement pattern of the sub-pixels SPix in the transmitting state and the sub-pixels SPix in the non-transmitting state for each of the detection periods SF1, SF2, and SF3. Thus, the detection device 1A can generate the color image at a resolution equal to or finer than the arrangement pitches PS1 and PS2 of the photodiodes 30.

### Modification of Second Embodiment

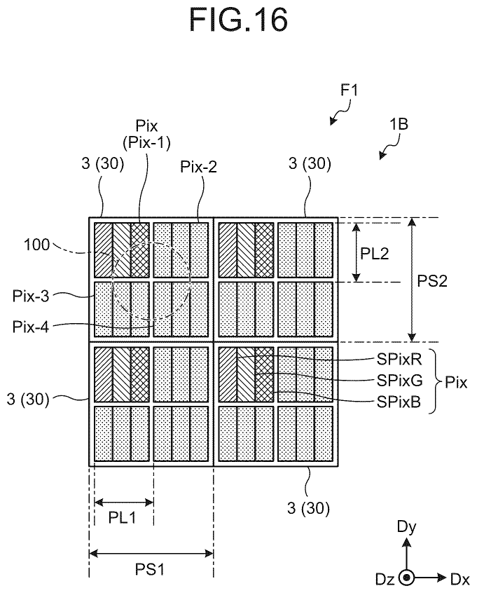

FIG. 16 is an explanatory diagram for explaining an exemplary detection operation of a detection device according to a modification of the second embodiment. In a detection device 1B according to the modification of the second embodiment, the liquid crystal panel 50A is the same as that of the second embodiment described above (refer to FIGS. 13 and 14) and includes the color filter CF and the sub-pixels SPix.

As illustrated in FIG. 16, the liquid crystal panel 50A simultaneously brings the first sub-pixel SPixR, the second sub-pixel SPixG, and the third sub-pixel SPixB of the first pixel Pix-1 into the transmitting state in the detection period F1. The liquid crystal panel 50A brings the second pixel Pix-2, the third pixel Pix-3, and the fourth pixel Pix-4 into the non-transmitting state in the detection period F1. That is, the light transmitted through the first pixel Pix-1 is white light, and the liquid crystal panel 50A emits monochrome light toward the photodiode 30.

In the detection device 1B according to the modification of the second embodiment, a monochrome image can be generated even when the liquid crystal panel 50A is configured with the color filter CF and the sub-pixels SPix. In this case, the time required for detection is shortened and the load required for processing various types of information by the host IC70 is reduced as compared with the second embodiment. The detection devices 1A and 1B in the second embodiment and the modification thereof have the common configuration in which the liquid crystal panel 50A includes the color filter CF and the sub-pixels SPix, and can switch between the detection of monochrome images and the detection of color images by driving the pixels Pix differently.

### Third Embodiment

FIG. 17 is a plan view schematically illustrating an arrangement relation between the pixels of the liquid crystal panel and the sensor pixels of the optical sensor in a detection device according to a third embodiment. In the first embodiment, and the second embodiment and the modification thereof described above, the configuration has been described in which the arrangement pitches PS1 and PS2 of the photodiodes 30 are integer multiples of the arrangement pitches PL1 and PL2 of the pixels Pix, but the present disclosure is not limited to this configuration.

As illustrated in FIG. 17, in a detection device 1C according to the third embodiment, the arrangement pitches PS1 and PS2 of the photodiodes 30 are non-integer multiples of the arrangement pitches PL1 and PL2 of the pixels Pix. Specifically, 10 rows and 10 columns of the pixels Pix are arranged so as to overlap the photodiodes 30 arranged in 3 rows and 3 columns. That is, the arrangement pitches PS1 and PS2 of the photodiodes 30 are approximately 3.33 times the arrangement pitches PL1 and PL2 of the pixels Pix.

In the present embodiment, at least one of the pixels Pix is located overlapping a boundary BD between adjacent two of the photodiodes 30. In the present embodiment, in the same way as in the first embodiment described above, the arrangement pattern of the pixels Pix in the transmitting state and the pixels Pix in the non-transmitting state is changed for each of the detection periods F.

As for the pixels Pix that do not overlap the boundary BD between the photodiodes 30, the photodiode 30 outputs the sensor value So for each of the pixels Pix, in the same way as in the first embodiment described above. In contrast, when the pixel Pix overlapping the boundary BD between the photodiodes 30 is in the transmitting state (indicated by a sign Pix-on in FIG. 17), the light transmitted through the pixel Pix in the transmitting state is dividedly applied to two of the photodiodes 30. Therefore, near the boundary BD, the amount of the light applied to each of the two photodiodes 30 decreases, and the detection sensitivity may decrease.

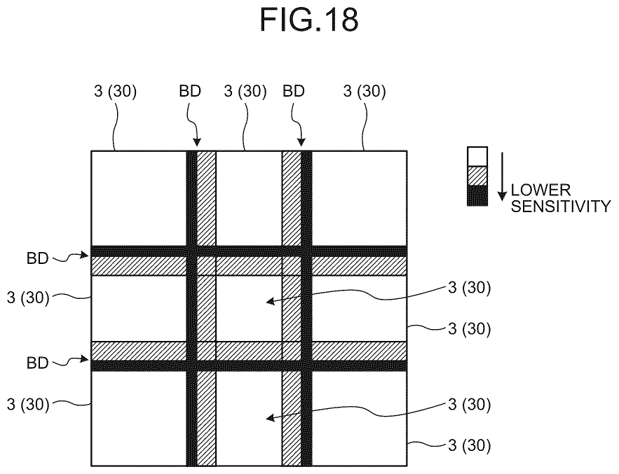

FIG. 18 is a plan view illustrating an exemplary sensitivity map of the optical sensor according to the third embodiment. The sensitivity map illustrated in FIG. 18 illustrates a distribution of the detection sensitivity of the photodiodes 30. The distribution of the detection sensitivity is specifically the distribution of gradation values in the combined image. However, the sensitivity map is not limited to this example and may use other values, such as the sensor values So. In the sensitivity map illustrated in FIG. 18, the sensitivity decreases in the order of a white region, a hatched region, and a black region. In the sensitivity map, the hatched region and the black region are regions along the boundaries BD of the photodiodes 30.

As illustrated in FIG. 17, the pixels Pix overlapping the boundary BD are arranged in a biased manner so as to be asymmetric with respect to the boundary BD. That is, a first overlapping area differs in size from a second overlapping area, wherein the first overlapping area is the overlapping area between one pixel Pix overlapping the boundary BD and one of the photodiodes 30 adjacent to each other with the boundary BD therebetween, and the second overlapping area is the overlapping area between the one pixel Pix and the other of the photodiodes 30 adjacent to each other with the boundary BD therebetween. As a result, as illustrated in FIG. 18, the vicinity of the boundary BD has the black region having lower sensitivity and the hatched region having medium sensitivity.

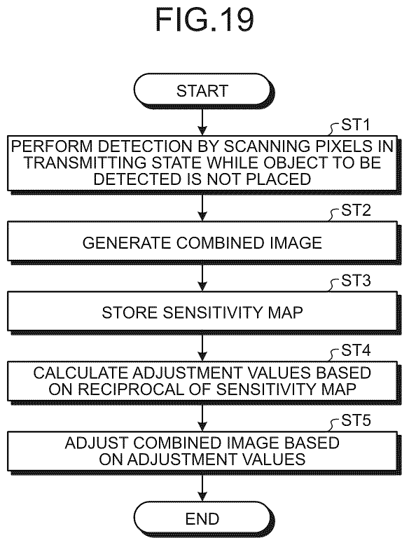

The following describes a method for adjusting the sensor values So using the sensitivity map. FIG. 19 is a flowchart for explaining a method for calculating the adjustment values by the detection device according to the third embodiment. As illustrated in FIG. 19, the detection device 1C performs the detection by scanning the pixels Pix in the transmitting state while the object to be detected 100 is not placed in the detection area AA (Step ST1).

In the same way as in the first embodiment described above, the combined image generation circuit 76 integrates the sensor values So based on the detection signals (sensor values So) in each of the detection periods F and the information (positional information) on the pixels Pix in the transmitting state in each of the detection periods F. The combined image generation circuit 76 thereby generates one combined image while the object to be detected 100 is not placed in the detection area AA (Step ST2).

The sensitivity map storage circuit 72 (refer to FIG. 2) stores therein the combined image obtained at Step ST2 as the sensitivity map (Step ST3). The sensitivity map storage circuit 72 stores therein, for example, the distribution of the gradation values of the combined image as the sensitivity map. In the sensitivity map in FIG. 18, for example, the gradation value in the white region is set to 256; the gradation value in the hatched region is set to a gradation A (A<256); the gradation value in the black region is set to a gradation B (B<A); and the sensitivity map storage circuit 72 stores therein the distribution of these gradation values.

The adjustment value generation circuit 73 calculates the adjustment values for the gradation values of the combined image acquired by the photodiodes 30. The adjustment value generation circuit 73 (refer to FIG. 2) calculates the adjustment values based on the reciprocal of the sensitivity map stored in advance in the sensitivity map storage circuit 72 (Step ST4). In this case, the reciprocal of the sensitivity map is coefficients corresponding to the reciprocals of the gradation values. When the gradation value in the white region is 256, the gradation value in the hatched region is 171 (A), and the gradation value in the black region is 85 (B), the adjustment value generation circuit 73 calculates the adjustment value in the white region as 1 (=256/256), the adjustment value in the hatched region as 256/A, and the adjustment value in the black region as 256/B.

Thus, the adjustment value generation circuit 73 generates the adjustment values to increase the gradation of the acquired combined image in the region where one of the pixels Pix is located overlapping the boundary BD between adjacent two of the photodiodes 30.

The combined image generation circuit 76 adjusts the combined image of the object to be detected 100 based on the adjustment value calculated by the adjustment value generation circuit 73 (step ST5). This operation adjusts the gradation values near the boundary BD where the detection sensitivity is lower, thus obtaining a good combined image.

Thus, the detection device 1C can adjust the combined image based on the sensitivity map obtained in advance. Therefore, even when the arrangement pitches PS1 and PS2 of the photodiodes 30 are not integer multiples of the arrangement pitches PL1 and PL2 of the pixels Pix, the detection device 1C can adjust the distribution of the detection sensitivity to obtain the good combined image. In other words, the detection device 1C of the present embodiment can improve the flexibility of the arrangement of the photodiodes 30 and the pixels Pix.

The method for calculating the adjustment values by the adjustment value generation circuit 73 has been described above for ease of understanding, and any method may be used. In the present embodiment, the example in which the liquid crystal panel 50 emits the monochrome light has been described, but the present embodiment is not limited to this example and can be combined with the second embodiment. That is, the detection device 1C may generate the adjustment values for a red (R) image by the first sub-pixels SPixR, the adjustment values for a green (G) image by second sub-pixel SPixG, and the adjustment values for a blue (B) image by the third sub-pixel SPixB.

While the preferred embodiments have been described above, the present disclosure is not limited to the embodiments described above. The content disclosed in the embodiments is merely an example, and can be variously modified within the scope not departing from the gist of the present disclosure. Any modifications appropriately made within the scope not departing from the gist of the present disclosure also naturally belong to the technical scope of the present disclosure. At least one of various omissions, substitutions, and changes of the components can be made without departing from the gist of the embodiments and the modification described above.

What is claimed is:

1. A detection device comprising:
a photodiode provided on a substrate;
a light source disposed so as to face the photodiode; and
a liquid crystal panel disposed between the photodiode and the light source in a direction orthogonal to the substrate, wherein
the liquid crystal panel comprises a plurality of pixels,
in plan view, the photodiode has a size larger than a size of each of the pixels, and the photodiode is disposed in a position overlapping the pixels, and
the liquid crystal panel is configured to bring at least one of the pixels overlapping the photodiode into a transmitting state and bring another of the pixels into a non-transmitting state.

2. The detection device according to claim 1, comprising a plurality of the photodiodes arranged on the substrate.

3. The detection device according to claim 2, wherein
the liquid crystal panel is configured to control the pixels such that the pixels in the transmitting state and the pixels in the non-transmitting state in a first direction are alternately arranged, and
an arrangement pitch in the first direction of the pixels in the transmitting state is equal or larger than an arrangement pitch in the first direction of the photodiodes.

4. The detection device according to claim 1, wherein
the liquid crystal panel is configured to sequentially scan the pixel in the transmitting state among the pixels overlapping the photodiode in each of detection periods, and
the photodiode is configured to sequentially output a detection signal corresponding to light transmitted through the pixel in the transmitting state in each of the detection periods.

5. The detection device according to claim 4, comprising a combined image generation circuit configured to generate one combined image by combining images in a plurality of the detection periods based on a plurality of the detection signals output in each of the detection periods and information on the pixel in the transmitting state in each of the detection periods.

6. The detection device according to claim 2, wherein
at least one of the pixels is disposed overlapping a boundary between adjacent two of the photodiodes, and
the detection device comprises:
a storage circuit configured to store a distribution of detection sensitivity of the photodiodes; and
an adjustment value generation circuit configured to calculate, based on the distribution of detection sensitivity, an adjustment value for gradations of an image acquired by the photodiodes.

7. The detection device according to claim 6, wherein the adjustment value generation circuit is configured to generate the adjustment value to increase the gradations of the acquired image in a region where the one of the pixels is disposed overlapping the boundary between the adjacent two of the photodiodes.

8. The detection device according to claim 2, wherein an arrangement pitch in a first direction of the photodiodes is an integer multiple of an arrangement pitch in the first direction of the pixels.

9. The detection device according to claim 1, wherein the liquid crystal panel is configured to emit monochrome light toward the photodiode.

10. The detection device according to claim 1, wherein each of the pixels of the liquid crystal panel comprises a first sub-pixel comprising a first-color color filter, a second sub-pixel comprising a second-color color filter, and a third sub-pixel comprising a third-color color filter.

11. The detection device according to claim 10, wherein
the liquid crystal panel is configured to:
have a first period, a second period, and a third period arranged in a time-division manner; and
bring the first sub-pixel into the transmitting state during the first period, the second sub-pixel into the transmitting state during the second period, and the third sub-pixel into the transmitting state during the third period.

12. The detection device according to claim 10, wherein the liquid crystal panel is configured to simultaneously bring the first sub-pixel, the second sub-pixel, and the third sub-pixel into the transmitting state.

13. The detection device according to claim 1, wherein the light source is configured to emit parallel light toward the liquid crystal panel.
